(19) United States
(12) Patent Application Publication
(10) Pub. No.: US 2023/0369437 A1
(43) Pub. Date: Nov. 16, 2023

(54) SEMICONDUCTOR DEVICE AND METHOD OF MANUFACTURING SEMICONDUCTOR DEVICE

(71) Applicant: SUMITOMO ELECTRIC DEVICE INNOVATIONS, INC., Kanagawa (JP)

(72) Inventor: Hiroaki KATO, Kanagawa (JP)

(21) Appl. No.: 18/152,396

(22) Filed: Jan. 10, 2023

(30) Foreign Application Priority Data
May 12, 2022 (JP) 2022-078634

(51) Int. Cl. H01L 29/45; H01L 23/31; H01L 29/20; H01L 29/778; H01L 21/02; H01L 29/40; H01L 29/66

(52) U.S. Cl. CPC H01L 29/452; H01L 21/02244; H01L 23/3171; H01L 29/2003; H01L 29/401; H01L 29/66462; H01L 29/7786

(57) ABSTRACT

A semiconductor device includes a semiconductor layer, a first insulating film provided on the semiconductor layer, a first opening being formed in the first insulating film, an ohmic electrode that is in ohmic contact with the semiconductor layer through the first opening, a gate electrode provided on the first insulating film, and a second insulating film covering at least a portion of a side surface of the ohmic electrode, the side surface being closer to the gate electrode, and the second insulating film being continuous with the first insulating film.

### CROSS-REFERENCE TO RELATED APPLICATIONS

This application claims priority to Japanese Pat. Application No. 2022-078634, filed on May 12, 2022, the entire subject matter of which is incorporated herein by reference.

### TECHNICAL FIELD

The present disclosure relates to a semiconductor device and a method of manufacturing the semiconductor device.

### BACKGROUND

Japanese Laid-Open Pat. Application Publication No. 2019-216188 (Patent Document 1) discloses a method of manufacturing a semiconductor device, including forming a silicon nitride film on a semiconductor layer, forming an opening in the silicon nitride film, and forming an ohmic electrode in the opening.

### SUMMARY

According to an embodiment of the present disclosure, a semiconductor device includes a semiconductor layer, a first insulating film provided on the semiconductor layer, a first opening being formed in the first insulating film, an ohmic electrode that is in ohmic contact with the semiconductor layer through the first opening, a gate electrode provided on the first insulating film, and a second insulating film covering at least a portion of a side surface of the ohmic electrode, the side surface being closer to the gate electrode, and the second insulating film being continuous with the first insulating film.

### BRIEF DESCRIPTION OF THE DRAWINGS

FIG. 1 is a cross-sectional view illustrating a semiconductor device according to a first embodiment;

FIG. 2 is a cross-sectional view (1) illustrating a method of manufacturing the semiconductor device according to the first embodiment;

FIG. 3 is a cross-sectional view (2) illustrating the method of manufacturing the semiconductor device according to the first embodiment;

FIG. 4 is a cross-sectional view (3) illustrating the method of manufacturing the semiconductor device according to the first embodiment;

FIG. 5 is a cross-sectional view (4) illustrating the method of manufacturing the semiconductor device according to the first embodiment;

FIG. 6 is a cross-sectional view (5) illustrating the method of manufacturing the semiconductor device according to the first embodiment;

FIG. 7 is a cross-sectional view (6) illustrating the method of manufacturing the semiconductor device according to the first embodiment;

FIG. 8 is a cross-sectional view (7) illustrating the method of manufacturing the semiconductor device according to the first embodiment;

FIG. 9 is a cross-sectional view (8) illustrating the method of manufacturing the semiconductor device according to the first embodiment;

FIG. 10 is a cross-sectional view (9) illustrating the method of manufacturing the semiconductor device according to the first embodiment;

FIG. 11 is a cross-sectional view illustrating a semiconductor device according to a modified example of the first embodiment;

FIG. 12 is a cross-sectional view illustrating a semiconductor device according to a second embodiment;

FIG. 13 is a cross-sectional view (1) illustrating a method of manufacturing the semiconductor device according to the second embodiment;

FIG. 14 is a cross-sectional view (2) illustrating the method of manufacturing the semiconductor device according to the second embodiment;

FIG. 15 is a cross-sectional view (3) illustrating the method of manufacturing the semiconductor device according to the second embodiment;

FIG. 16 is a cross-sectional view (4) illustrating the method of manufacturing the semiconductor device according to the second embodiment;

FIG. 17 is a cross-sectional view illustrating a semiconductor device according to a first modified example of the second embodiment;

FIG. 18 is a cross-sectional view illustrating a semiconductor device according to a second modified example of the second embodiment;

FIG. 19 is a cross-sectional view illustrating a semiconductor device according to a third modified example of the second embodiment, and

FIG. 20 is a cross-sectional view illustrating a semiconductor device according to a fourth modified example of the second embodiment.

### DETAILED DESCRIPTION

In recent years, miniaturization of a semiconductor device has been advanced, and a leakage current may increase with the semiconductor device being miniaturized.

According to the present disclosure, a leakage current can be suppressed.

### Description of Embodiments of the Present Disclosure

First, embodiments of the present disclosure will be listed and described.

[1] A semiconductor device according to an aspect of the present disclosure includes a semiconductor layer, a first insulating film provided on the semiconductor layer, a first opening being formed in the first insulating film, an ohmic electrode that is in ohmic contact with the semiconductor layer through the first opening, a gate electrode provided on the first insulating film, and a second insulating film covering at least a portion of a side surface of the ohmic electrode, the side surface being closer to the gate electrode, and the second insulating film being continuous with the first insulating film.

Because the second insulating film covering at least the portion of the side surface of the ohmic electrode on the gate electrode side is continuous with the first insulating film, the ohmic electrode is electrically insulated from the upper surface of the first insulating film by the second insulating film. Therefore, the leakage current flowing through the upper surface of the first insulating film between the ohmic electrode and the gate electrode can be suppressed.

[2] In [1], the first insulating film may be a nitride film, and the second insulating film may be an oxide film. In this case, the surface of the semiconductor layer is easily protected by the first insulating film, and the second insulating film can be formed by oxidation of the ohmic electrode.

[3] In [1] or [2], the thickness of the second insulating film may be 3 nm or greater. As the thickness of the second insulating film increases, the leakage current is suppressed more easily.

[4] In any one of [1] to [3], the second insulating film may be in contact with the upper surface of the first insulating film. In this case, the electrical resistance is easily increased with respect to the leakage current flowing through the upper surface of the first insulating film between the ohmic electrode and the gate electrode, and the leakage current is easily suppressed.

[5] In [4], in cross-sectional view, the second insulating film may be in contact over a range of 3 nm or greater with the upper surface of the first insulating film. As the range in which the second insulating film is in contact with the upper surface of the first insulating film is widened, the leakage current is suppressed more easily.

[6] A semiconductor device according to another aspect of the present disclosure includes a semiconductor layer, a first insulating film provided on the semiconductor layer, a first opening and a second opening being formed in the first insulating film, an ohmic electrode that is in ohmic contact with the semiconductor layer through the first opening, a gate electrode that is in Schottky contact with the semiconductor layer through the second opening, a second insulating film covering a side surface of the ohmic electrode, the side surface being closer to the gate electrode, and the second insulating film being in contact over a range of 3 nm or greater with an upper surface of the first insulating film in cross-sectional view. The first insulating film is a nitride film and the second insulating film is an oxide film.

Because the second insulating film covering the side surface of the ohmic electrode on the gate electrode side is in contact over a range of 3 nm or greater with the upper surface of the first insulating film for each portion in contact with the upper surface of the first insulating film (each contact portion) in cross-sectional view, the ohmic electrode is electrically insulated from the upper surface of the first insulating film by the second insulating film. Therefore, the leakage current flowing through the upper surface of the first insulating film between the ohmic electrode and the gate electrode can be suppressed.

[7] A method of manufacturing a semiconductor device according to another aspect of the present disclosure includes forming a first insulating film on a semiconductor layer, forming a first opening in the first insulating film, forming an ohmic electrode that is in ohmic contact with the semiconductor layer through the first opening, forming a gate electrode on the first insulating film, and forming a second insulating film covering at least a portion of a side surface of the ohmic electrode, the side surface being closer to the gate electrode, and the second insulating film being continuous with the first insulating film.

Because the second insulating film that covers at least the portion of the side surface of the ohmic electrode on the gate electrode side and that is continuous with the first insulating film is formed, the ohmic electrode is electrically insulated from the upper surface of the first insulating film by the second insulating film. Therefore, the leakage current flowing through the upper surface of the first insulating film between the ohmic electrode and the gate electrode can be suppressed.

[8] In [7], the forming of the second insulating film may include oxidizing the side surface of the ohmic electrode. In this case, the second insulating film is easily formed.

### Details of the Embodiments of the Present Disclosure

In the following, the embodiments of the present disclosure will be described in detail, but the present disclosure is not limited thereto. Here, in the present specification and the drawings, elements having substantially the same functional configuration are referenced by the same reference numerals, and description thereof may be omitted.

### (First Embodiment)

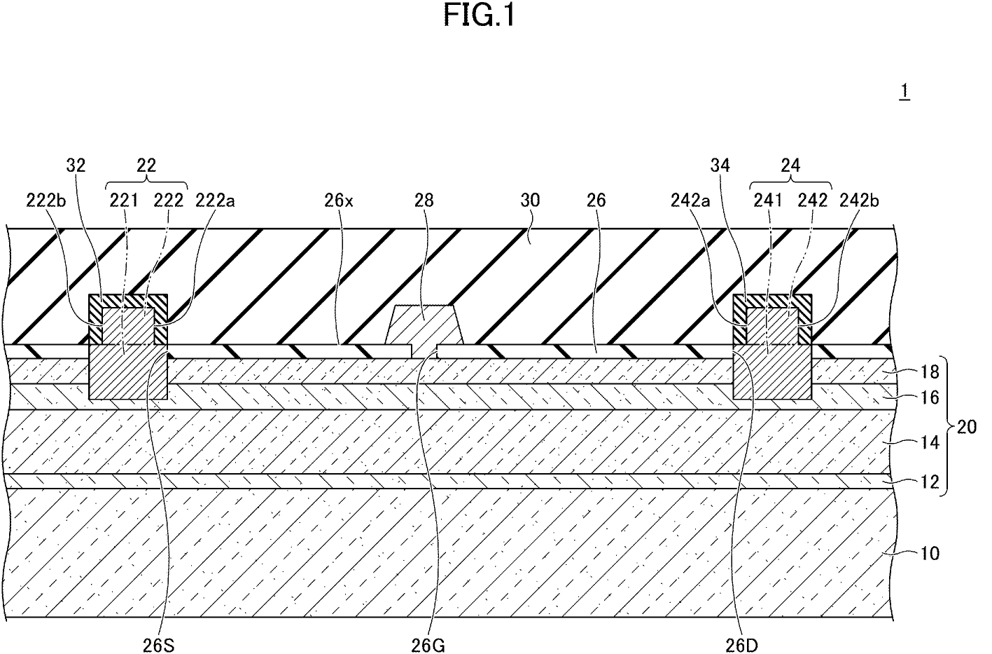

First, a first embodiment will be described. The first embodiment relates to a semiconductor device including a GaN-based high electron mobility transistor (HEMT). FIG. 1 is a cross-sectional view illustrating the semiconductor device according to the first embodiment.

As illustrated in FIG. 1, the semiconductor device 1 according to the first embodiment includes a substrate 10 and a laminated structure 20. The substrate 10 is, for example, a SiC substrate having a (0001) plane, and the lamination direction of the laminated structure 20 is, for example, a [0001] direction. The laminated structure 20 is provided on the substrate 10. The laminated structure 20 includes a nucleation layer 12, a channel layer 14, a barrier layer 16, and a cap layer 18. The laminated structure 20 is an example of a semiconductor layer.

The nucleation layer 12 is formed on the substrate 10. The nucleation layer 12 is, for example, an AlN layer, and the thickness of the nucleation layer 12 is 5 nm to 20 nm. The nucleation layer 12 functions as a seed layer for the channel layer 14.

The channel layer 14 is formed on the nucleation layer 12 by epitaxial growth. The channel layer 14 is, for example, an undoped GaN layer, and the thickness of the channel layer 14 is 500 nm. The channel layer 14 functions as an electron transit layer.

The barrier layer 16 is formed on the channel layer 14 by epitaxial growth. For example, the barrier layer 16 is an AlGaN layer, an InAlN layer, or an InAlGaN layer, and the thickness of the barrier layer 16 is from 5 nm to 30 nm. The band gap of the barrier layer 16 is greater than the band gap of the channel layer 14. When the barrier layer 16 is an AlGaN layer, the Al composition of the barrier layer 16 is, for example, 0.15 or greater and 0.35 or less. The conductivity type of the barrier layer 16 is n-type or undoped. The barrier layer 16 and the channel layer 14 may be in contact with each other, or a spacer layer, which is not illustrated, may be interposed between the barrier layer 16 and the channel layer 14. Strain is generated between the barrier layer 16 and the channel layer 14 due to a difference in lattice constant therebetween. Therefore, a two-dimensional electron gas (2DEG) derived from the piezoelectric charge is generated in a region on the channel layer 14 side in the vicinity of the interface between the barrier layer 16 and the channel layer 14, and a channel region is formed. The barrier layer 16 functions as an electron supply layer.

The cap layer 18 is formed on the barrier layer 16 by epitaxial growth. For example, the cap layer 18 is a GaN layer, and the thickness of the cap layer 18 is 5 nm. For example, the conductivity type of the cap layer 18 is n-type.

The semiconductor device 1 includes a passivation film 26. For example, the passivation film 26 is a nitride film such as a silicon nitride film, and the thickness of the passivation film 26 is from 10 nm to 100 nm. A source opening 26S, a drain opening 26D, and a gate opening 26G are formed in the passivation film 26. The laminated structure 20 is exposed from the passivation film 26 at the source opening 26S, the drain opening 26D, and the gate opening 26G. Specifically, in the source opening 26S and the drain opening 26D, the cap layer 18 is removed and the barrier layer 16 is exposed. In the gate opening 26G, the cap layer 18 is exposed. The passivation film 26 is an example of a first insulating film. The source opening 26S and the drain opening 26D are examples of a first opening, and the gate opening 26G is an example of a second opening.

The semiconductor device 1 includes a source electrode 22, a drain electrode 24, and a gate electrode 28. The source electrode 22 and the drain electrode 24 are arranged in order along the surface of the substrate 10.

The source electrode 22 covers the source opening 26S of the passivation film 26 and is in ohmic contact with the barrier layer 16 through the source opening 26S. The drain electrode 24 covers the drain opening 26D of the passivation film 26 and is in ohmic contact with the barrier layer 16 through the drain opening 26D. The source electrode 22 and the drain electrode 24 are formed by heat treatment of a titanium (Ti) layer and an aluminum (Al) layer provided in order from the laminated structure 20 side. The source electrode 22 and the drain electrode 24 are examples of an ohmic electrode.

The source electrode 22 has a lower portion 221 in the source opening 26S and an upper portion 222 on the lower portion 221. The lower portion 221 is in contact with the sidewall surfaces of the source opening 26S. The upper portion 222 has a pair of side surfaces 222a and 222b, and the side surfaces 222a and 222b are located inside the sidewall surfaces of the source opening 26S in plan view. The side surfaces 222a and 222b are substantially perpendicular to the upper surface 26x of the passivation film 26. Thus, the cross-sectional shape of the upper portion 222 is substantially rectangular.

The drain electrode 24 has a lower portion 241 in the drain opening 26D and an upper portion 242 on the lower portion 241. The lower portion 241 is in contact with the sidewall surfaces of the drain opening 26D. The upper portion 242 has a pair of side surfaces 242a and 242b, and the side surfaces 242a and 242b are located inside the sidewall surfaces of the drain opening 26D in plan view. The side surfaces 242a and 242b are substantially perpendicular to the upper surface 26x of the passivation film 26. Thus, the cross-sectional shape of the upper portion 242 is substantially rectangular.

The gate electrode 28 is provided between the source electrode 22 and the drain electrode 24 on the laminated structure 20. The gate electrode 28 covers the gate opening 26G of the passivation film 26 and is in Schottky contact with the cap layer 18 through the gate opening 26G. The gate electrode 28 includes, for example, a nickel (Ni) layer, a gold (Au) layer, and a tantalum (Ta) layer provided in order from the laminated structure 20 side.

The side surface 222a of the source electrode 22 is closer to the gate electrode 28 and the drain electrode 24 than the side surface 222b is, and the side surface 242a of the drain electrode 24 is closer to the gate electrode 28 and the source electrode 22 than the side surface 242b is.

The semiconductor device 1 includes insulating films 32 and 34. The insulating film 32 covers the side surfaces 222a and 222b of the source electrode 22. The insulating film 34 covers the side surfaces 242a and 242b of the drain electrode 24. The insulating films 32 and 34 are in contact with the passivation film 26 and are continuous with the passivation film 26. The insulating film 32 also covers the upper surface of the source electrode 22, and the insulating film 34 also covers the upper surface of the drain electrode 24. In plan view, the side surface of the insulating film 32 is located at the same position as the sidewall surface of the source opening 26S or is located inside the sidewall surface of the source opening 26S, and the side surface of the insulating film 34 is located at the same position as the sidewall surface of the drain opening 26D or is located inside the drain opening 26D. For example, the insulating films 32 and 34 are oxide films such as aluminum oxide films, and the thicknesses of the insulating films 32 and 34 are 3 nm or greater and 20 nm or less. The insulating films 32 and 34 are examples of a second insulating film.

The semiconductor device 1 includes an insulating film 30. The insulating film 30 is a protective film that covers the gate electrode 28. The insulating film 30 is made of an insulating material containing Si, and is, for example, a SiN film, a SiO₂ film, or a SiON film. For example, the thickness of the insulating film 30 is 200 nm to 400 nm.

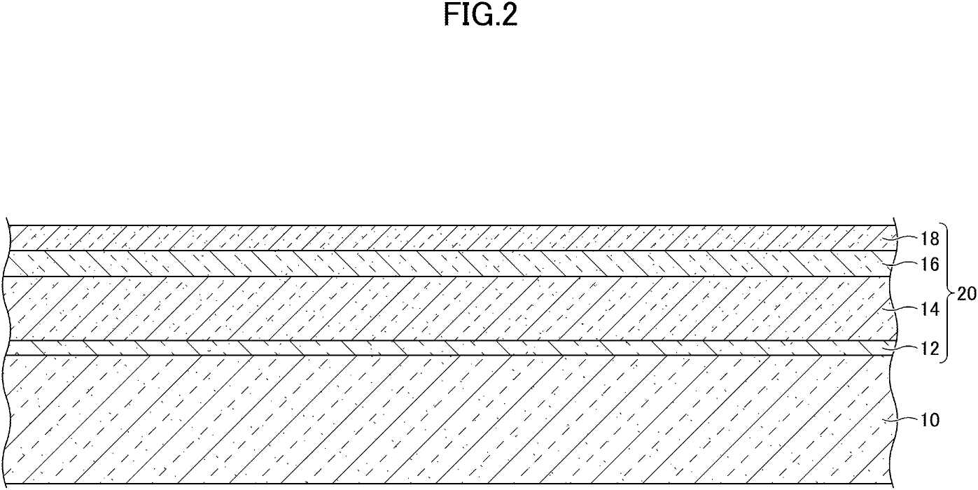

Next, a method of manufacturing the semiconductor device 1 according to the first embodiment will be described. FIGS. 2 to 10 are cross-sectional views illustrating the method of manufacturing the semiconductor device according to the first embodiment.

First, as illustrated in FIG. 2, the laminated structure 20 including multiple nitride semiconductor layers is grown on the substrate 10 by using a metal organic chemical vapor deposition (MOCVD) method. Specifically, first, the nucleation layer 12 is grown on the substrate 10. When the nucleation layer 12 is an AlN layer, the source gas is, for example, trimethylaluminum (TMA) and ammonia (NH₃), and the growth temperature is, for example, 1100° C. Next, the channel layer 14 is grown on the nucleation layer 12. When the channel layer 14 is a GaN layer, the source gas is, for example, trimethylgallium (TMG) and NH₃, and the growth temperature is, for example, 1050° C. Subsequently, the barrier layer 16 is grown on the channel layer 14. When the barrier layer 16 is an AlGaN layer, the source gas is, for example, TMA, TMG, and NH₃, and the growth temperature is, for example, 1050° C. Subsequently, the cap layer 18 is grown on the barrier layer 16. When the cap layer 18 is a GaN layer, the source gas is, for example, TMG and NH₃, and the growth temperature is, for example, 1050° C.

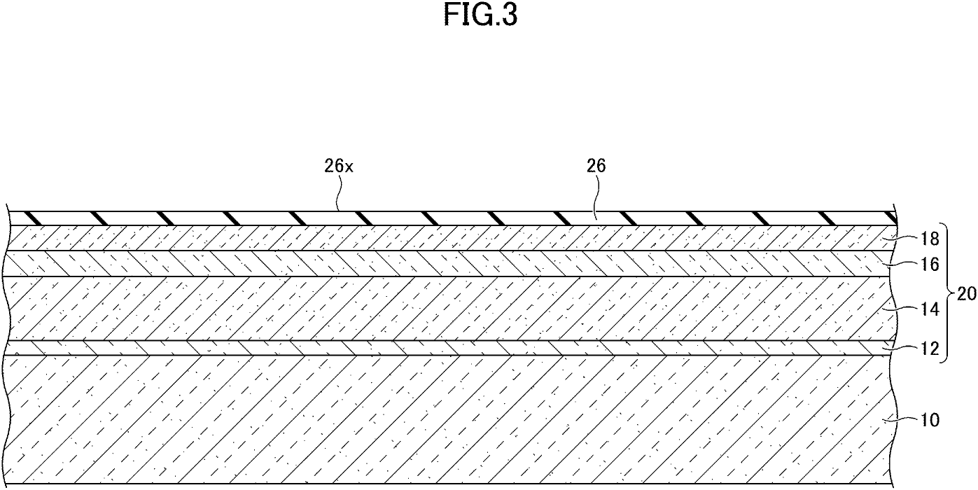

Next, as illustrated in FIG. 3, the passivation film 26 that is in contact with the upper surface of the laminated structure 20 is formed using a low-pressure CVD method or a plasma CVD method. For example, when the low-pressure CVD method is used, the deposition temperature is set to 600° C. to 850° C., and the growth pressure is set to 10 Pa to 50 Pa, for example. The passivation film 26 formed by the low-pressure CVD method becomes denser and harder than the passivation film 26 formed by the plasma CVD method. After a portion (a lower layer portion) of the passivation film 26 is formed by the low-pressure CVD method, a remaining portion (an upper layer portion) of the passivation film 26 may be formed by the plasma CVD method. When the passivation film 26 is formed by the low-pressure CVD method, ammonia gas and dichlorosilane (SiH₂Cl₂) are used as the source gas.

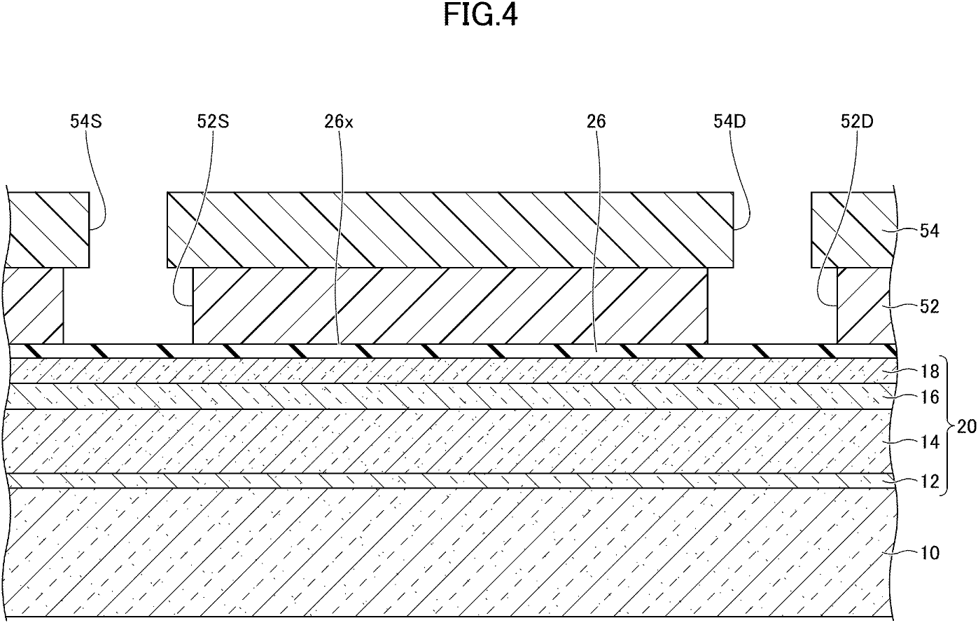

Next, as illustrated in FIG. 4, a photoresist 52 and a photoresist 54 are applied in this order on the passivation film 26. For example, the material of the photoresist 54 is polymethylglutarimide (PMGI), and the photoresist 54 is an i-line resist. Next, by photolithography, an opening 54S for a source and an opening 54D for a drain are formed in the photoresist 54, and an opening 52S for a source and an opening 52D for a drain are formed in the photoresist 52. A portion of the passivation film 26 is exposed through the openings 54S and 52S, and another portion of the passivation film 26 is exposed through the openings 54D and 52D.

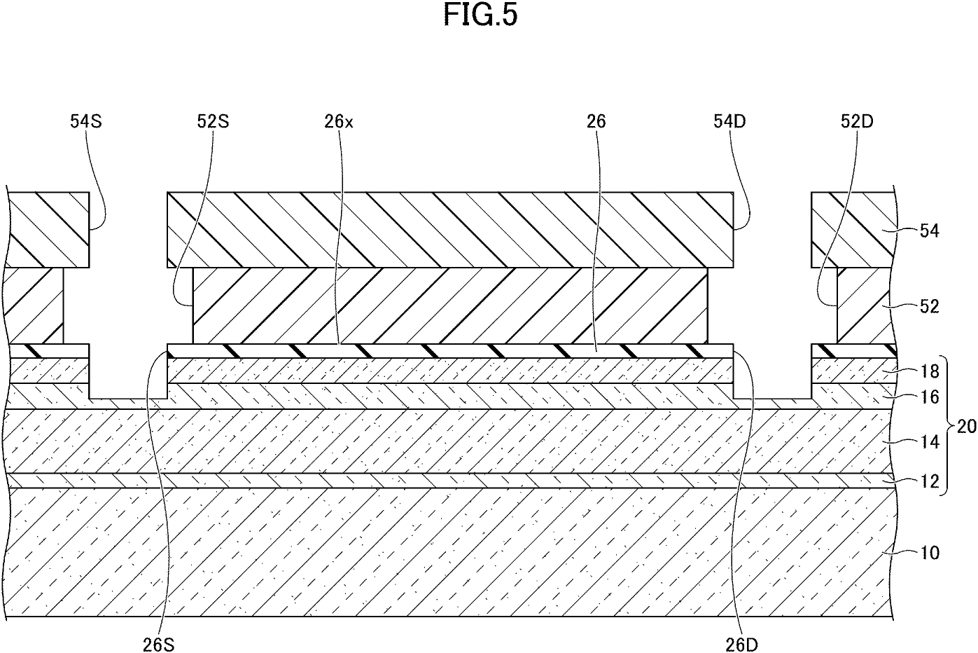

Next, as illustrated in FIG. 5, the source opening 26S and the drain opening 26D are formed in the passivation film 26 and the laminated structure 20 by reactive ion etching (RIE) by using the photoresists 52 and 54 as a mask. For example, a reactive gas containing fluorine (F) is used for the etching of the passivation film 26, and a reactive gas containing chlorine (Cl) is used for the etching of the laminated structure 20.

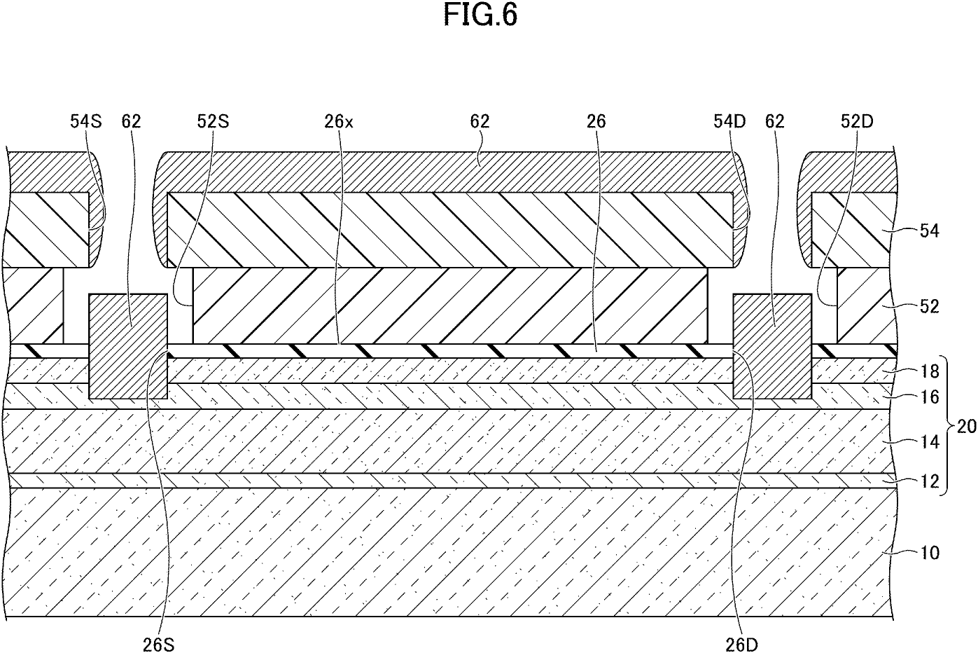

Next, as illustrated in FIG. 6, metal layers 62 are formed inside the source opening 26S and inside the drain opening 26D by vapor deposition. The metal layers 62 are formed so as to project upward from the source opening 26S and the drain opening 26D. The metal layers 62 are also attached to the upper surface of the photoresist 54, the sidewall surfaces of the opening 54S, and the sidewall surfaces of the opening 54D. The metal layer 62 includes, for example, a Ti layer and an Al layer formed in order from the substrate 10 side. For example, the thickness of the Ti layer is 30 nm and the thickness of the Al layer is 300 nm.

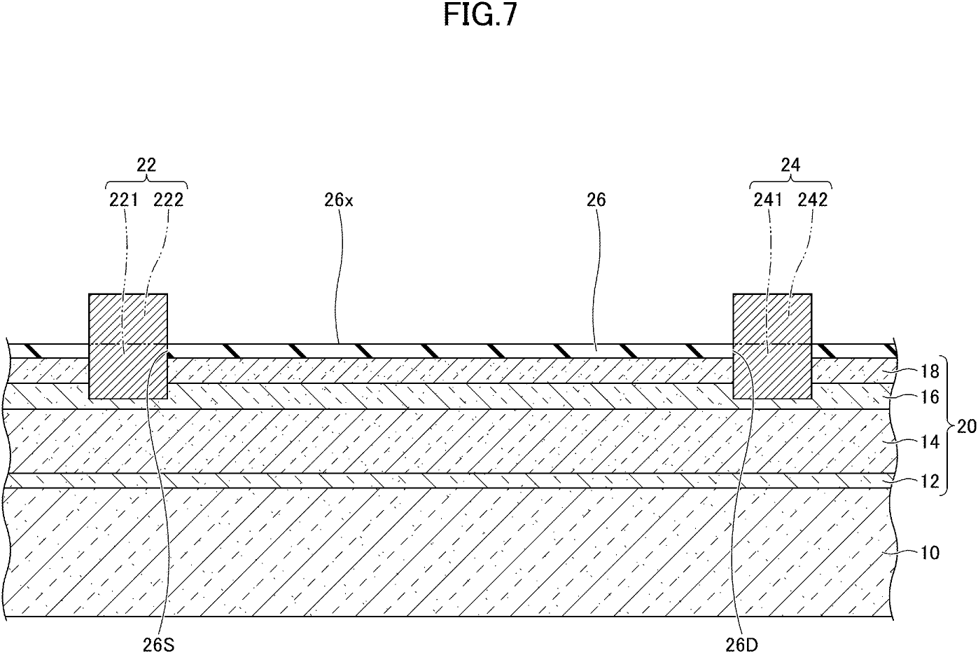

Next, as illustrated in FIG. 7, the photoresists 52 and 54 are removed. With the photoresist 54 being removed, the metal layers 62 attached to the photoresist 54 are also removed. With respect to the above, the metal layers 62 remain inside the source opening 26S and the drain opening 26D. That is, lift-off is performed. As a result, the source electrode 22 is formed in the source opening 26S, and the drain electrode 24 is formed in the drain opening 26D. The source electrode 22 has the lower portion 221 in the source opening 26S and the upper portion 222 on the lower portion 221. The drain electrode 24 has the lower portion 241 in the drain opening 26D and the upper portion 242 on the lower portion 241. The side surface of the upper portion 222 may be substantially aligned with the sidewall surface of the source opening 26S, and the side surface of the upper portion 242 may be substantially aligned with the sidewall surface of the drain opening 26D. In order to obtain such a shape, the shapes of the photoresists 52 and 54 may be adjusted, or the source opening 26S and the drain opening 26D may be widened by etching.

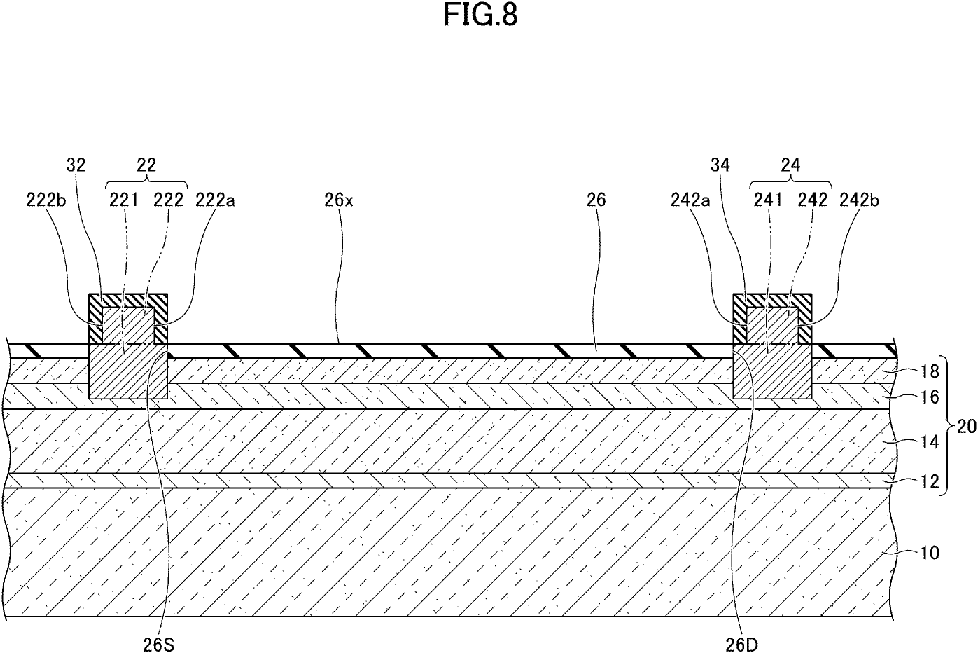

Next, as illustrated in FIG. 8, the insulating films 32 and 34 are formed by oxidizing the surfaces of the source electrode 22 and the drain electrode 24. The source electrode 22 and the drain electrode 24 are oxidized by, for example, plasma oxidation. The insulating film 32 covers the side surfaces 222a and 222b of the source electrode 22, and the insulating film 34 covers the side surfaces 242a and 242b of the drain electrode 24. The insulating films 32 and 34 are in contact with the passivation film 26 and are continuous with the passivation film 26.

Next, the source electrode 22 and the drain electrode 24 are alloyed by heat treatment. The alloying temperature is, for example, 600° C. As a result, the source electrode 22 and the drain electrode 24 come into ohmic contact with the laminated structure 20.

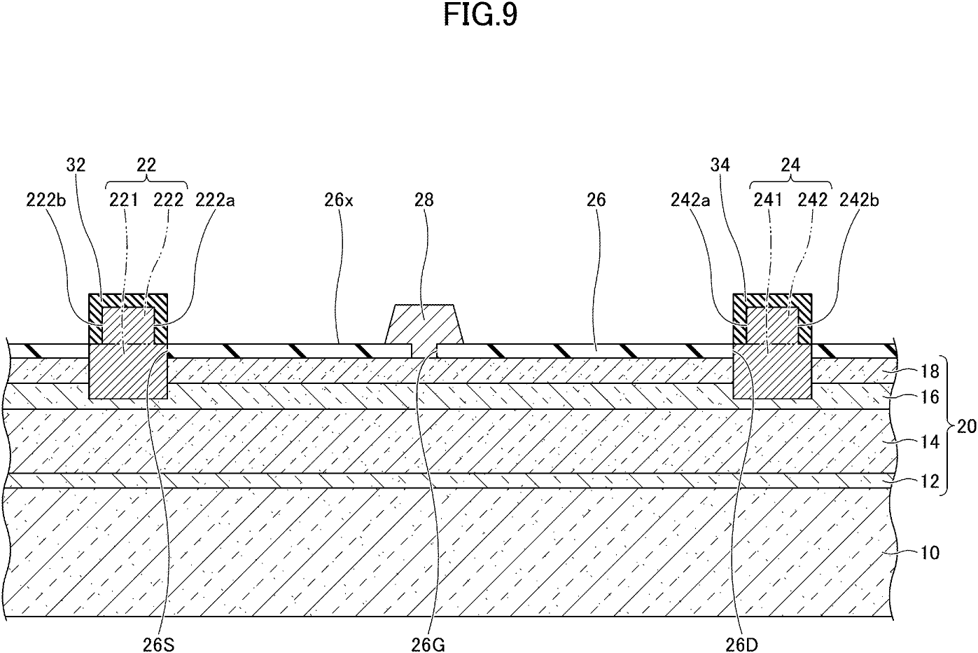

Next, as illustrated in FIG. 9, the gate opening 26G is formed in the passivation film 26. In the formation of the gate opening 26G, a resist mask having an opening corresponding to the gate opening 26G is formed on the passivation film 26, and the passivation film 26 is etched through the resist mask. For example, a reactive gas containing fluorine is used for the etching of the passivation film 26. Subsequently, the resist mask is removed. Next, the gate electrode 28 that is in Schottky contact with the laminated structure 20 through the gate opening 26G is formed. The gate electrode 28 includes, for example, an Ni layer, an Au layer, and a Ta layer formed in order from the substrate 10 side.

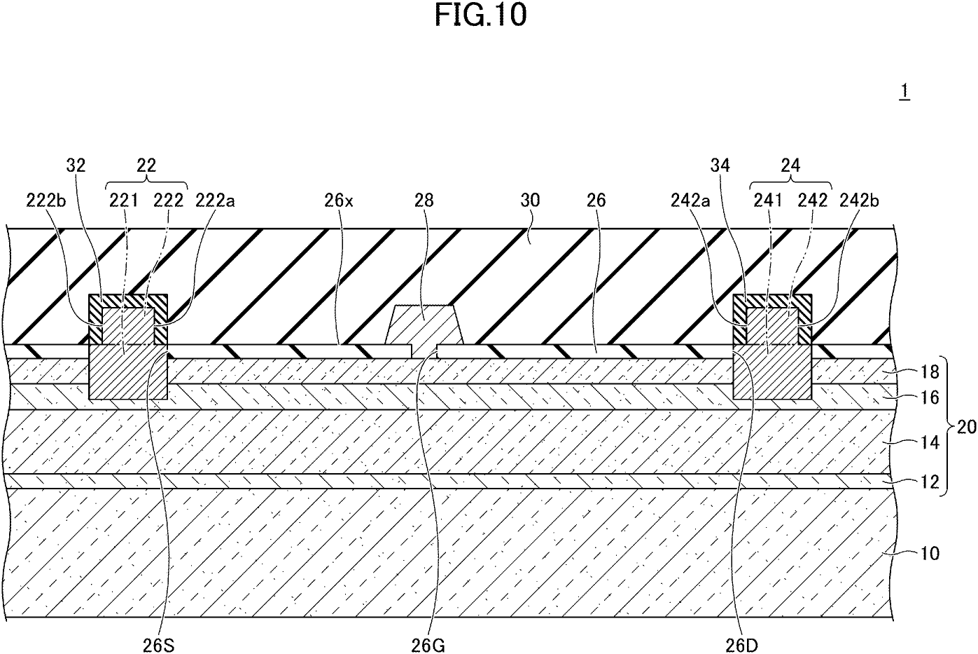

Next, as illustrated in FIG. 10, the insulating film 30 that covers the gate electrode 28 is formed on the passivation film 26. The insulating film 30 is formed by, for example, a plasma CVD method.

Subsequently, wiring and the like are formed as necessary. As described, the semiconductor device 1 according to the first embodiment can be manufactured.

In the first embodiment, the insulating film 32 is formed on the side surface 222a of the source electrode 22, the insulating film 34 is formed on the side surface 242a of the drain electrode 24, and the insulating films 32 and 34 are continuous with the passivation film 26. Thus, the source electrode 22 and the drain electrode 24 are electrically insulated from the upper surface 26x of the passivation film 26 by the insulating films 32 and 34. Additionally, compared with the state before the insulating films 32 and 34 are formed, the distance between the source electrode 22 and the gate electrode 28 is increased by the thickness of the insulating film 32, and the distance between the drain electrode 24 and the gate electrode 28 is increased by the thickness of the insulating film 34. Therefore, the leakage current flowing through the upper surface 26x of the passivation film 26 between the source electrode 22 and the gate electrode 28 can be suppressed. Similarly, the leakage current flowing through the upper surface 26x of the passivation film 26 between the drain electrode 24 and the gate electrode 28 can be suppressed.

Additionally, because the passivation film 26 is a nitride film, the surface of the laminated structure 20 of the semiconductor is easily protected by the passivation film 26. Additionally, because the insulating films 32 and 34 are oxide films, the insulating films 32 and 34 can be formed by oxidation of ohmic electrodes.

As described above, the thicknesses of the insulating films 32 and 34 are, for example, 3 nm or greater. Although a natural oxide film is formed on the surface of aluminum, the thickness of the natural oxide film is 2 nm at most and the natural oxide film does not function as an insulating film. The thicknesses of the insulating films 32 and 34 are preferably 5 nm or greater, and more preferably 10 nm or greater. As the thicknesses of the insulating films 32 and 34 increase, the leakage current can be easily suppressed. On the side surface 222a, the thickness of the insulating film 32 is the thickness in a direction perpendicular to the side surface 222a, and on the side surface 222b, the thickness of the insulating film 32 is the thickness in a direction perpendicular to the side surface 222b. On the side surface 242a, the thickness of the insulating film 34 is the thickness in a direction perpendicular to the side surface 242a, and on the side surface 242b, the thickness of the insulating film 34 is the thickness in a direction perpendicular to the side surface 242b.

The interface between the source electrode 22 and the insulating film 32 and the interface between the drain electrode 24 and the insulating film 34 can be identified by energy dispersive X-ray spectroscopy (EDX) using a scanning transmission electron microscope (STEM) or a transmission electron microscope (TEM). In the present disclosure, it is assumed that, in a line scan waveform acquired by EDX, the interface is present at a position where detected waveforms of main elements in respective constituent layers intersect.

### (Modified Example of the First Embodiment)

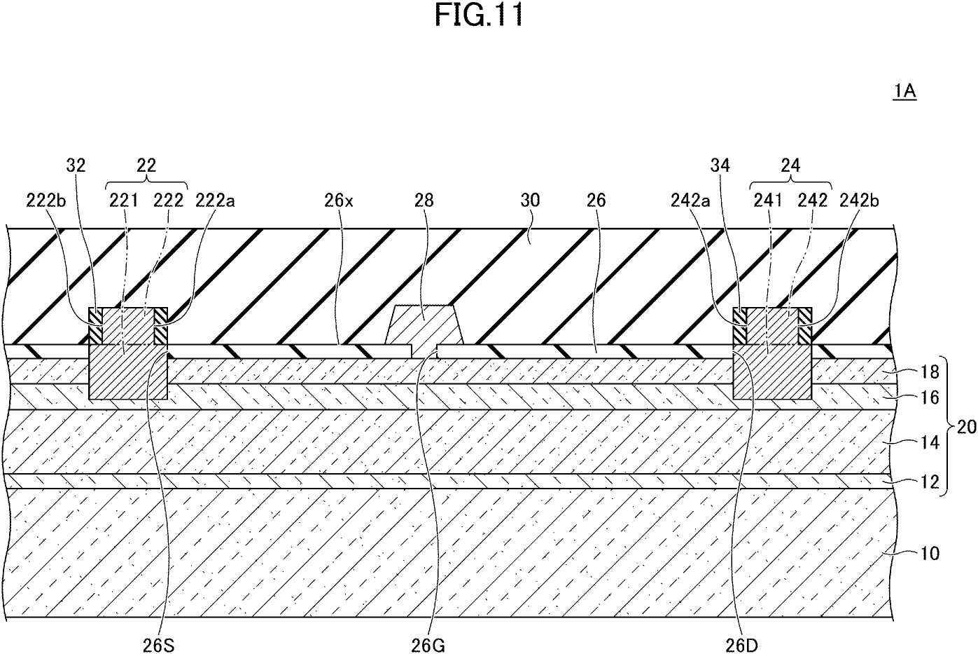

Next, a modified example of the first embodiment will be described. FIG. 11 is a cross-sectional view illustrating a semiconductor device according to the modified example of the first embodiment.

In a semiconductor device 1A according to the modified example of the first embodiment, as illustrated in FIG. 11, the insulating film 32 covers the side surfaces 222a and 222b of the source electrode 22, but the insulating film 32 does not cover the upper surface of the source electrode 22. Additionally, the insulating film 34 covers the side surfaces 242a and 242b of the drain electrode 24, but the insulating film 34 does not cover the upper surface of the drain electrode 24. The upper surface of the source electrode 22 and the upper surface of the drain electrode 24 are covered by the insulating film 30.

The other configurations are substantially the same as those of the first embodiment.

According to the modified example of the first embodiment, substantially the same effect as that of the first embodiment can be obtained.

### (Second Embodiment)

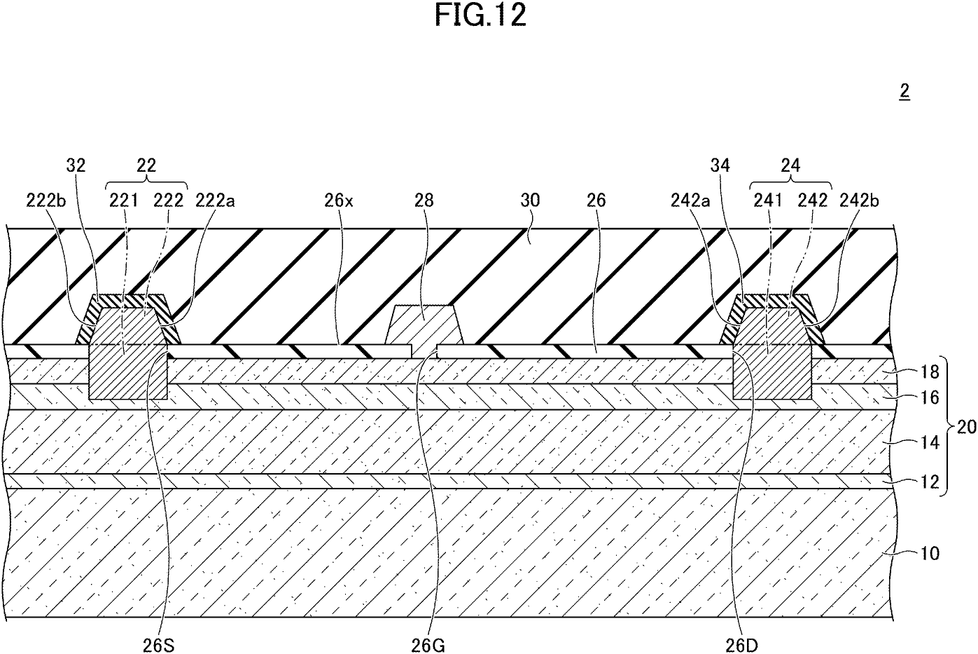

Next, a second embodiment will be described. FIG. 12 is a cross-sectional view illustrating a semiconductor device according to the second embodiment.

As illustrated in FIG. 12, in a semiconductor device 2 according to the second embodiment, the side surfaces 222a and 222b of the upper portion 222 of the source electrode 22 are inclined with respect to a plane perpendicular to the upper surface 26x of the passivation film 26. The side surfaces 222a and 222b approach each other more as the distance from the laminated structure 20 increases. That is, the cross-sectional shape of the upper portion 222 is substantially trapezoidal.

Additionally, the side surfaces 242a and 242b of the upper portion 242 of the drain electrode 24 are inclined with respect to a plane perpendicular to the upper surface 26x of the passivation film 26. The side surfaces 242a and 242b approach each other more as the distance from the laminated structure 20 increases. That is, the cross-sectional shape of the upper portion 242 is substantially trapezoidal.

The insulating film 32 covers the side surfaces 222a and 222b of the source electrode 22 and is in contact with the upper surface 26x of the passivation film 26. The insulating film 34 covers the side surfaces 242a and 242b of the drain electrode 24 and is in contact with the upper surface 26x of the passivation film 26. The insulating films 32 and 34 are continuous with the passivation film 26. For example, the insulating films 32 and 34 are in contact over a range of 3 nm or greater with the upper surface 26x of the passivation film 26 for each contact portion in cross-sectional view.

The other configurations are substantially the same as those of the first embodiment.

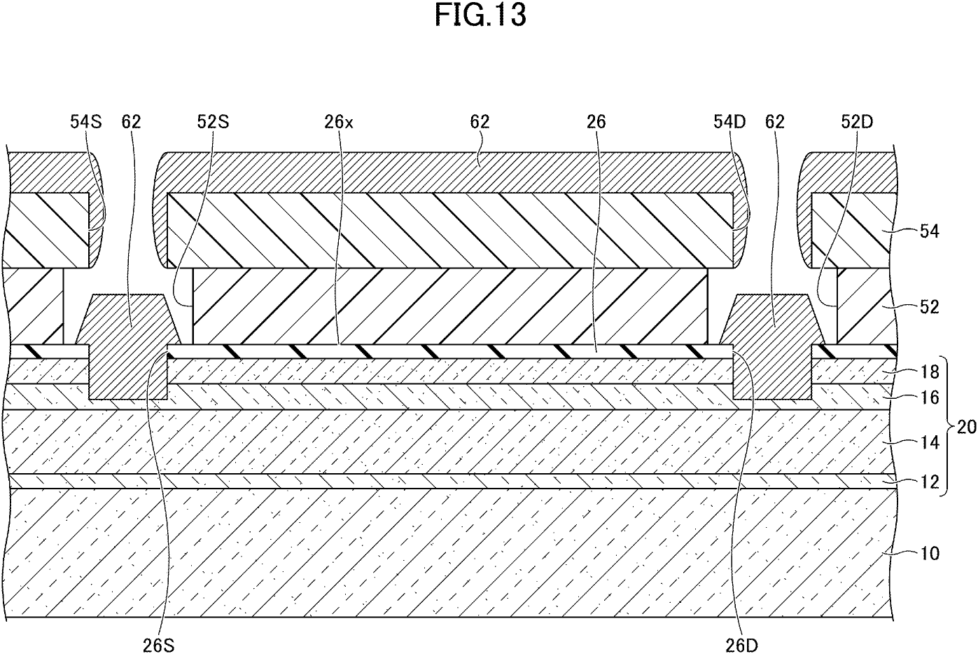

Next, a method of manufacturing the semiconductor device 2 according to the second embodiment will be described. FIGS. 13 to 16 are cross-sectional views illustrating the method of manufacturing the semiconductor device according to the second embodiment.

First, as in the first embodiment, the processes up to the formation of the source opening 26S and the drain opening 26D are performed (see FIG. 5). Next, as illustrated in FIG. 13, the metal layers 62 are formed inside the source opening 26S and inside the drain opening 26D by vapor deposition. At this time, the metal layers 62 are formed not only inside the source opening 26S and inside the drain opening 26D, but also on the passivation film 26 at the sides of the source opening 26S and the drain opening 26D such that the metal layers 62 rest on the passivation film 26. As in the first embodiment, the metal layers 62 are also attached to the upper surface of the photoresist 54, the sidewall surfaces of the opening 54S, and the sidewall surfaces of the opening 54D.

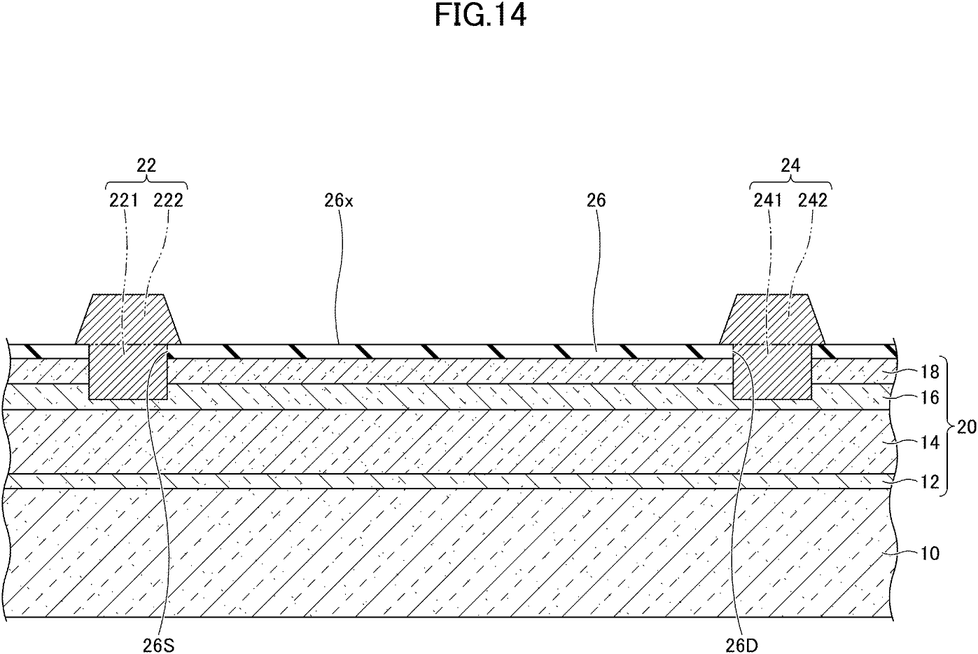

Next, as illustrated in FIG. 14, the photoresists 52 and 54 are removed. As a result, the source electrode 22 including a portion resting on the passivation film 26 and the drain electrode 24 including a portion resting on the passivation film 26 are formed.

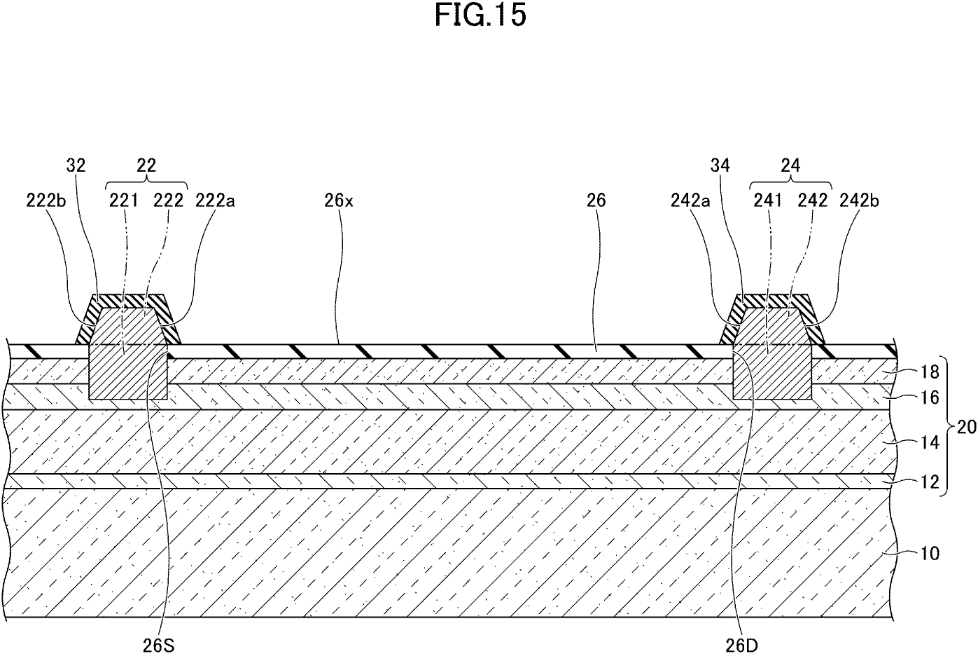

Next, as illustrated in FIG. 15, the insulating films 32 and 34 are formed by oxidizing the surfaces of the source electrode 22 and the drain electrode 24. Next, the source electrode 22 and the drain electrode 24 are alloyed by heat treatment. As a result, the source electrode 22 and the drain electrode 24 come into ohmic contact with the laminated structure 20.

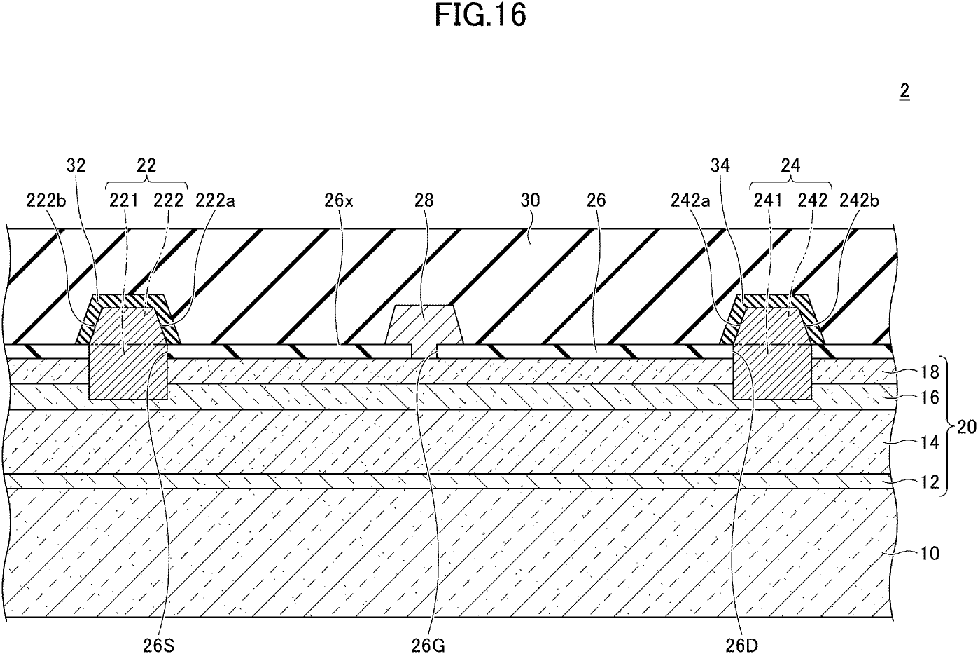

Next, as illustrated in FIG. 16, as in the first embodiment, the gate opening 26G is formed in the passivation film 26, the gate electrode 28 is formed, and the insulating film 30 is formed.

Subsequently, wiring and the like are formed as necessary. As described, the semiconductor device 2 according to the second embodiment can be manufactured.

According to the second embodiment, substantially the same effect as that of the first embodiment can be obtained. According to the second embodiment, the insulating films 32 and 34 are in contact with the upper surface 26x of the passivation film 26. Therefore, the leakage current flowing through the upper surface 26x of the passivation film 26 can be further suppressed. Furthermore, the metal layers 62 can be formed not only inside the source opening 26S and inside the drain opening 26D but also on the passivation film 26 at the sides of the source opening 26S and the drain opening 26D such that the metal layers rest on the passivation film 26. Therefore, the source opening 26S and the drain opening 26D can be easily filled with the metal layers 62.

As described above, the insulating films 32 and 34 are in contact over a range of 3 nm or greater with the upper surface 26x of the passivation film 26 for each contact portion in cross-sectional view. Even if a natural oxide film is formed on the surface of aluminum, a natural oxide film does not become thick enough to be in contact over a range of 3 nm or greater with the upper surface 26x of the passivation film 26 for each contact portion in cross-sectional view. The insulating films 32 and 34 are preferably in contact over a range of 5 nm or greater with the upper surface 26x of the passivation film 26 for each contact portion in cross-sectional view, and are preferably in contact over a range of 10 nm or greater with the upper surface 26x of the passivation film 26 for each contact portion in cross-sectional view. As the range in which the insulating films 32 and 34 are in contact with the upper surface 26x of the passivation film 26 is wider, the leakage current is more easily suppressed.

In the second embodiment, the insulating films 32 and 34 are formed by oxidizing the entirety of the portions of the source electrode 22 and the drain electrode 24 that rest on the passivation film 26, but part of the portions of the source electrode 22 and the drain electrode 24 that rest on the passivation film 26 may be oxidized. That is, in the manufactured semiconductor device 2, a portion of the upper portion 222 of the source electrode 22 may be on the passivation film 26, and a portion of the upper portion 242 of the drain electrode 24 may be on the passivation film 26.

### (First Modified Example of the Second Embodiment)

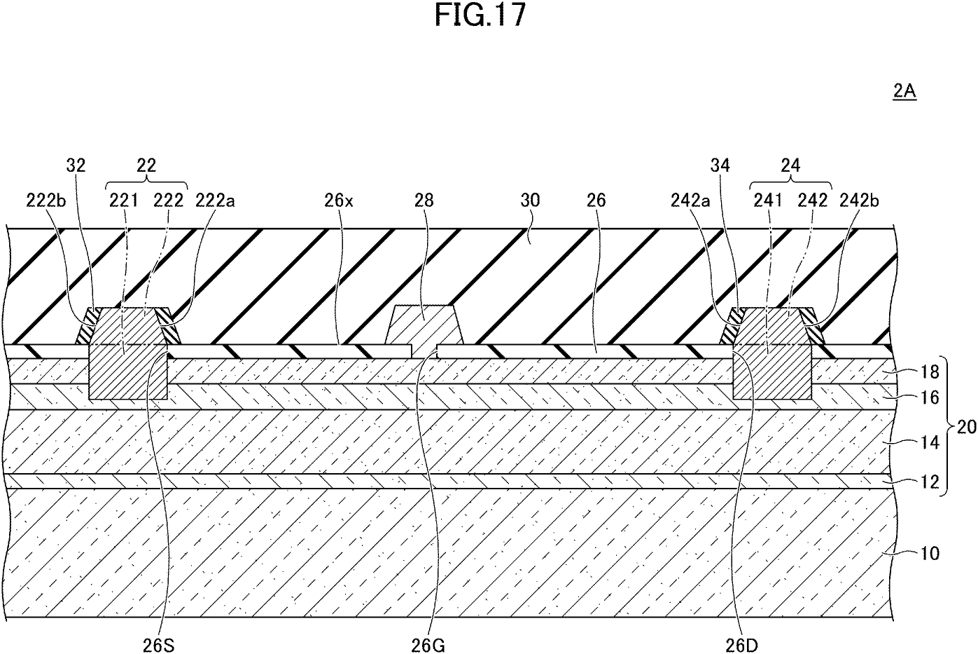

Next, a first modified example of the second embodiment will be described. FIG. 17 is a cross-sectional view illustrating a semiconductor device according to the first modified example of the second embodiment.

In a semiconductor device 2A according to the first modified example of the second embodiment, as illustrated in FIG. 17, the insulating film 32 covers the side surfaces 222a and 222b of the source electrode 22, but the insulating film 32 does not cover the upper surface of the source electrode 22. Additionally, the insulating film 34 covers the side surfaces 242a and 242b of the drain electrode 24, but the insulating film 34 does not cover the upper surface of the drain electrode 24. The upper surface of the source electrode 22 and the upper surface of the drain electrode 24 are covered by the insulating film 30.

The other configurations are substantially the same as those of the second embodiment.

According to the first modified example of the second embodiment, substantially the same effect as that of the second embodiment can also be obtained.

### (Second Modified Example of the Second Embodiment)

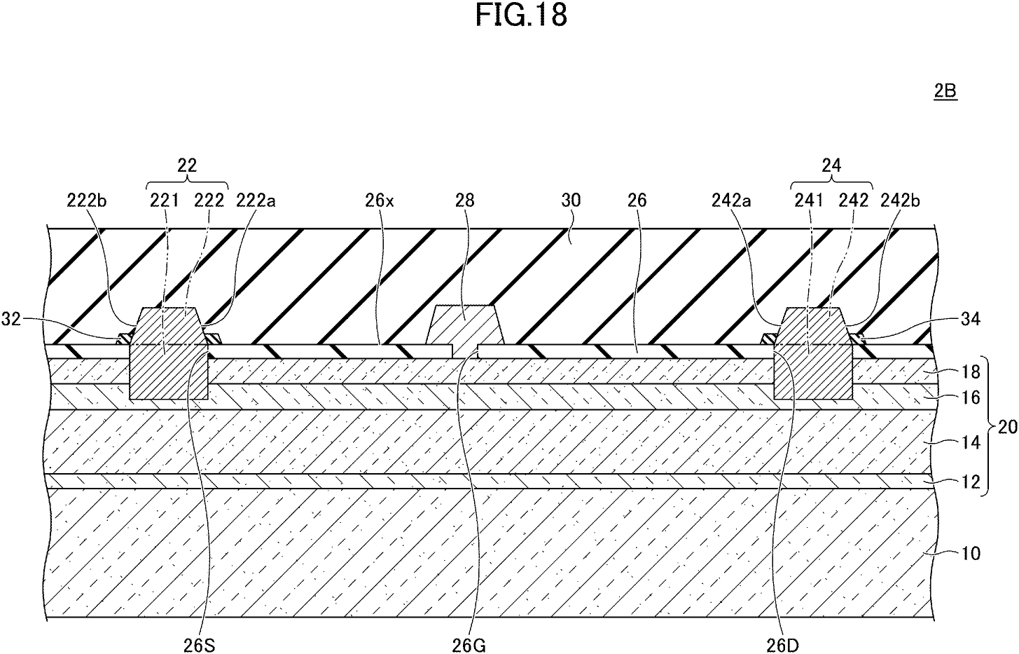

Next, a second modified example of the second embodiment will be described. FIG. 18 is a cross-sectional view illustrating a semiconductor device according to the second modified example of the second embodiment.

In a semiconductor device 2B according to the second modified example of the second embodiment, as illustrated in FIG. 18, the insulating film 32 covers a lower portion of each of the side surfaces 222a and 222b of the source electrode 22, and the insulating film 32 does not cover remaining portions of the side surfaces 222a and 222b. The insulating film 32 is in contact with the upper surface 26x of the passivation film 26 and is continuous with the passivation film 26. Additionally, the insulating film 34 covers a lower portion of each of the side surfaces 242a and 242b of the drain electrode 24, and the insulating film 32 does not cover remaining portions of the side surfaces 242a and 242b. The insulating film 34 is in contact with the upper surface 26x of the passivation film 26 and is continuous with the passivation film 26. The remaining portions of the side surfaces 222a and 222b and the remaining portions of the side surfaces 222a and 222b are covered by the insulating film 30.

The other configurations are substantially the same as those of the first modified example of the second embodiment.

According to the second modified example of the second embodiment, substantially the same effect as that of the second embodiment can be obtained.

### (Third Modified Example of the Second Embodiment)

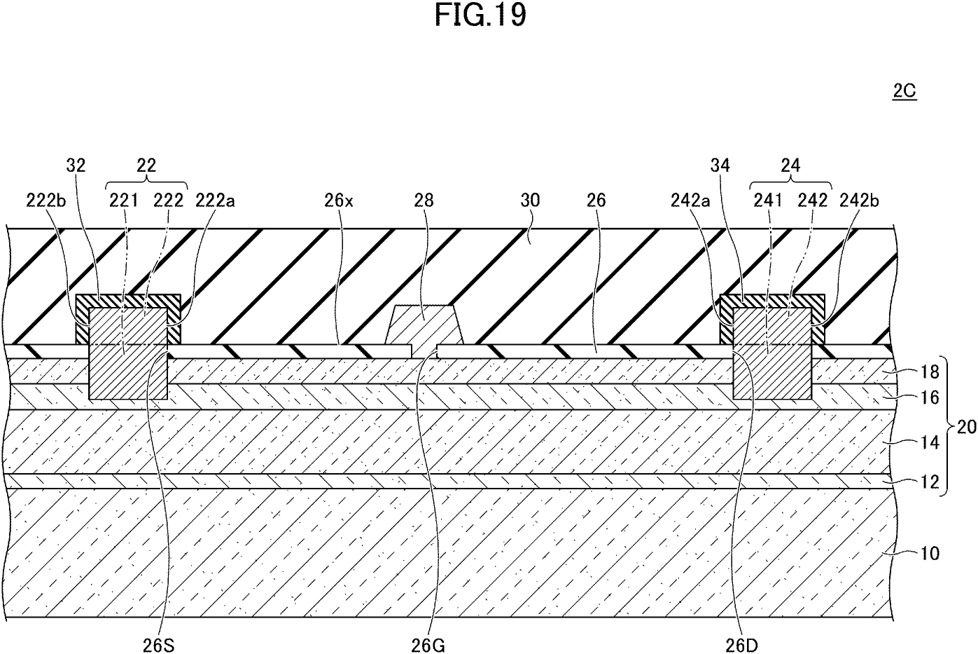

Next, a third modified example of the second embodiment will be described. FIG. 19 is a cross-sectional view illustrating a semiconductor device according to the third modified example of the second embodiment.

In a semiconductor device 2C according to the third modified example of the second embodiment, as illustrated in FIG. 19, the side surfaces 222a and 222b of the upper portion 222 of the source electrode 22 are substantially perpendicular to the upper surface 26x of the passivation film 26, and the cross-sectional shape of the upper portion 222 is substantially rectangular. Additionally, the side surfaces 242a and 242b of the upper portion 242 of the drain electrode 24 are substantially perpendicular to the upper surface 26x of the passivation film 26, and the cross-sectional shape of the upper portion 242 is substantially rectangular.

The insulating film 32 is in contact with the upper surface 26x of the passivation film 26 and is continuous with the passivation film 26. Additionally, the insulating film 34 is in contact with the upper surface 26x of the passivation film 26 and is continuous with the passivation film 26.

The other configurations are substantially the same as those of the second embodiment.

According to the third modified example, substantially the same effect as that of the second embodiment can be obtained.

### (Fourth Modified Example of the Second Embodiment)

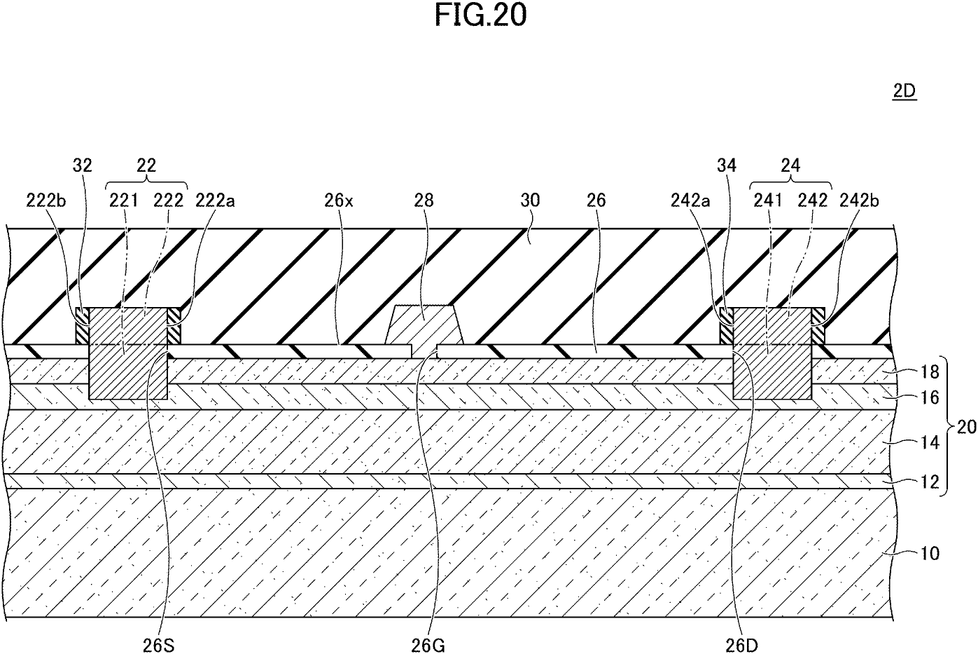

Next, a fourth modified example of the second embodiment will be described. FIG. 20 is a cross-sectional view illustrating a semiconductor device according to the fourth modified example of the second embodiment.

In a semiconductor device 2D according to the fourth modified example of the second embodiment, as illustrated in FIG. 20, the insulating film 32 covers the side surfaces 222a and 222b of the source electrode 22, but the insulating film 32 does not cover the upper surface of the source electrode 22. Additionally, the insulating film 34 covers the side surfaces 242a and 242b of the drain electrode 24, but the insulating film 34 does not cover the upper surfaces of the drain electrode 24. The upper surface of the source electrode 22 and the upper surface of the drain electrode 24 are covered by the insulating film 30.

The other configurations are substantially the same as those of the third modified example of the second embodiment.

According to the fourth modified example of the second embodiment, substantially the same effect as that of the second embodiment can be obtained.

Although the embodiments have been described in detail above, the invention is not limited to a specific embodiment, and various modifications and alterations can be made within the scope described in the claims.

What is claimed is:

1. A semiconductor device comprising:
a semiconductor layer;
a first insulating film provided on the semiconductor layer, a first opening being formed in the first insulating film;
an ohmic electrode that is in ohmic contact with the semiconductor layer through the first opening;
a gate electrode provided on the first insulating film; and
a second insulating film covering at least a portion of a side surface of the ohmic electrode, the side surface being closer to the gate electrode, and the second insulating film being continuous with the first insulating film.

2. The semiconductor device as claimed in claim 1, wherein the first insulating film is a nitride film and the second insulating film is an oxide film.

3. The semiconductor device as claimed in claim 1, wherein a thickness of the second insulating film is 3 nm or greater.

4. The semiconductor device as claimed in claim 1, wherein the second insulating film is in contact with an upper surface of the first insulating film.

5. The semiconductor device as claimed in claim 4, wherein the second insulating film is in contact over a range of 3 nm or greater with the upper surface of the first insulating film in cross-sectional view.

6. A semiconductor device comprising:
a semiconductor layer;
a first insulating film provided on the semiconductor layer, a first opening and a second opening being formed in the first insulating film;
an ohmic electrode that is in ohmic contact with the semiconductor layer through the first opening;
a gate electrode that is in Schottky contact with the semiconductor layer through the second opening;
a second insulating film covering a side surface of the ohmic electrode, the side surface being closer to the gate electrode, and the second insulating film being in contact over a range of 3 nm or greater with an upper surface of the first insulating film in cross-sectional view,
wherein the first insulating film is a nitride film and the second insulating film is an oxide film.

7. A method of manufacturing a semiconductor device, the method comprising:
forming a first insulating film on a semiconductor layer;
forming a first opening in the first insulating film;
forming an ohmic electrode that is in ohmic contact with the semiconductor layer through the first opening;
forming a gate electrode on the first insulating film; and
forming a second insulating film covering at least a portion of a side surface of the ohmic electrode, the side surface being closer to the gate electrode, and the second insulating film being continuous with the first insulating film.

8. The method of manufacturing the semiconductor device as claimed in claim 7, wherein the forming of the second insulating film includes oxidizing the side surface of the ohmic electrode.
